(19) United States
(12) Patent Application Publication
(10) Pub. No.: US 2025/0372145 A1
(43) Pub. Date: Dec. 4, 2025

(54) INTEGRATION OF IN-MEMORY ANALOG COMPUTING ARCHITECTURES WITH SYSTOLIC ARRAYS

(71) Applicant: University of South Carolina, Columbia, SC (US)

(72) Inventors: Mohammed Essa, San Jose, CA (US); Ramtin Mohammadizand, Irmo, SC (US); Brendan C. Reidy, Florence, SC (US)

(73) Assignee: University of South Carolina, Columbia, SC (US)

(21) Appl. No.: 19/225,634

(22) Filed: Jun. 2, 2025

Related U.S. Application Data
(60) Provisional application No. 63/655,305, filed on Jun. 3, 2024.
(60) Provisional application No. 63/655,715, filed on Jun. 4, 2024.

(51) Int. Cl. G11C 11/4063; G06F 9/54; G06F 15/80; G06N 3/048; G06N 3/065; G06N 3/082

(52) U.S. Cl. CPC G11C 11/4063; G06F 9/544; G06F 15/8046; G06N 3/048; G06N 3/065; G06N 3/082; G06F 2209/543

(57) ABSTRACT

The system architecture trained by a training component using a unified training component and method is a heterogeneous hardware that accelerates essential operations of artificial intelligence models by incorporating both systolic arrays and IMAC circuits. To leverage the strengths of systolic arrays for convolutional layers and the strengths of IMAC circuits for dense layers, the unified training component utilizes a training method with mixed-precision training techniques to train the different types of layers.

### CROSS-REFERENCE TO RELATED APPLICATIONS

This application claims the benefit of prior-filed, co-pending U.S. Provisional patent Applications Nos. 63/655,305, filed on Jun. 3, 2024, and 63/655,715, filed on Jun. 4, 2024, the contents of which are incorporated herein by reference in their entirety.

### BACKGROUND OF THE INVENTION

The present invention lies within the field of computer systems; more specifically, hardware systems and associated training methods for neural networks.

Deep learning models have been widely adopted in various real-life applications, including language translation, computer vision, healthcare, and self-driving cars. However, this has resulted in a significant increase in the computational demands of machine learning (ML) workloads, which conventional von Neumann architectures struggle to keep up with. To overcome this challenge, alternative architectures such as in-memory computing (IMC) have emerged. IMC architectures perform computations directly where the data exists, thus reducing the high energy costs of data transfers between memory and processor in data-intensive applications like ML. Conventional IMC architectures typically employ emerging technologies such as resistive random access memory (RRAM) and magnetoresistive random-access memory (MRAM) to accelerate matrix-vector multiplication (MVM) operations in the ML workloads through massive parallelism and analog computation. However, other functional blocks such as activation functions still rely on digital computation, resulting in energy overheads due to signal conversion units. In-memory analog computing (IMAC) architectures, on the other hand, are a class of IMC architectures, which realize both MVM operations and non-linear vector operation in the analog domain, and thus prevent the need for signal conversion units between deep neural networks (DNNs) layers. Previous research has shown that IMAC architectures can achieve orders of magnitude reduction in latency and energy consumption in implementing dense fully connected (FC) layers in DNNs. However, adapting IMAC architectures to implement convolutional layers in convolutional neural networks (CNNs) requires unrolling and reshaping the layers to MVM, resulting in large crossbar arrays that may be susceptible to reliability issues caused by noise and interconnect parasitic.

One of the most promising digital hardware accelerators introduced in recent years to accelerate ML workloads is the systolic array, a deeply-pipelined network of processing elements (PEs). Systolic arrays may be used in digital processors to perform parallel computing for neural network machine learning. Systolic arrays reduce energy consumption and increase performance by reusing the values fetched from memory and registers and reducing irregular intermediate memory accesses. Systolic arrays have demonstrated impressive results in executing the general matrix multiplication operation, which is a critical component of CNNs, specifically in convolutional layers. One example of a digital architecture which uses such a systolic array is a tensor processing unit (TPU), an AI accelerator application-specific integrated circuit (ASIC) developed by Google®. However, systolic arrays struggle to maintain the same level of performance when executing FC layers due to the vast number of weights that typically make up FC layers. This limits weight reuse and necessitates multiple iterations to execute, resulting in inefficient hardware utilization and high energy consumption.

It is therefore the object of this application to provide a hybrid systolic array-IMAC architecture trained by a unified training component to efficiently execute both convolutional and FC layers to improve performance and reduce memory bandwidth requirements for various-sized CNN models.

### BRIEF SUMMARY OF THE INVENTION

A hybrid computing device has an in-memory analog computing (IMAC) architecture including a plurality of interconnected subarrays, an analog-to-digital converter interconnecting the IMAC architecture with a memory unit, and a systolic array operably connected to the memory unit.

A method of using a unified training component to train the above hybrid computing device inserts a tanh activation function before a first dense fully connected (FC) layer and after a last convolutional layer of the IMAC to ensure that activations stay within a range of {-1, 1}, trains a plurality of FC layers and a plurality of convolutional layers using identical data to produce a plurality of trained FC layers and a plurality of trained convolutional layers, retrains an FC section of the IMAC to produce a plurality of retrained FC layers, and modifies the plurality of retrained FC layers based on characteristics of weights and activation functions of the IMAC.

The objects and advantages will appear more fully from the following detailed description made in conjunction with the accompanying drawings.

### BRIEF DESCRIPTION OF THE SEVERAL VIEWS OF THE DRAWING

FIG. 1A illustrates an exemplary structure of architecture for IMACs in a system architecture. FIG. 1B illustrates a magnified exemplary structure of an n×m IMAC subarray utilized in the architecture of FIG. 1A.

FIG. 2 illustrates an exemplary embodiment of the system architecture.

FIG. 3 illustrates a flowchart of an example of a method for using a unified training component to train a hybrid computing device according to certain embodiments.

FIG. 4 illustrates an example diagram of a computer system that may include the kinds of software programs, data stores, hardware, and interfaces that can implement and train a system architecture as disclosed herein and according to certain embodiments.

It should be understood that, for clarity, not all elements are necessarily labeled in all drawings. Lack of labeling in a figure should not be interpreted as lack of a feature.

### DETAILED DESCRIPTION OF THE INVENTION

In the present description, certain terms have been used for brevity, clearness and understanding. No unnecessary limitations are to be applied therefrom beyond the requirement of the prior art because such terms are used for descriptive purposes only and are intended to be broadly construed. The different systems and methods described herein may be used alone or in combination with other systems and methods. Dimensions and materials identified in the drawings and applications are by way of example only and are not intended to limit the scope of the claimed invention. Any other dimensions and materials not consistent with the purpose of the present application can also be used. Various equivalents, alternatives and modifications are possible within the scope of the appended claims. Each limitation in the appended claims is intended to invoke interpretation under 35 U.S.C. § 112, sixth paragraph, only if the terms “means for” or “step for” are explicitly recited in the respective limitation.

Digital units using systolic arrays have shown significant performance improvements when executing convolutional layers in CNNs. However, they struggle to maintain the same efficiency in FC layers, leading to suboptimal hardware utilization. IMAC architectures, on the other hand, have demonstrated notable speedup in executing FC layers, but inferior performance in executing convolutional layers. The systems and methods herein embody a novel, heterogeneous, mixed-signal, and mixed-precision architecture that integrates an IMAC unit with a digital unit incorporating a systolic array, such as an edge TPU, to enhance mobile CNN performance in such a way as to improve efficiency in both FC layers and convolutional layers simultaneously.

To leverage the strengths of systolic arrays for convolutional layers and the strengths of IMAC circuits for dense layers, a unified training component 160 utilizes a training method with mixed-precision training techniques to train the different types of layers. This training technique mitigates potential accuracy drops when deploying models on the system architecture, because each layer is trained using the techniques optimized for that type of layer. Utilizing this unified training component 160, the systolic array-IMAC configuration achieves up to 2.59× performance improvements, and 88% memory reductions compared to conventional systolic array architectures for various CNN models while maintaining comparable accuracy. The systolic array-IMAC architecture shows potential for various applications where energy efficiency and high performance are desired, such as, but not limited to, edge computing and real-time processing in mobile devices. The unified training component 160 and the integration of IMAC and systolic array architectures contribute to the potential impact of invention on the broader machine learning landscape by allowing faster systems which consume less power.

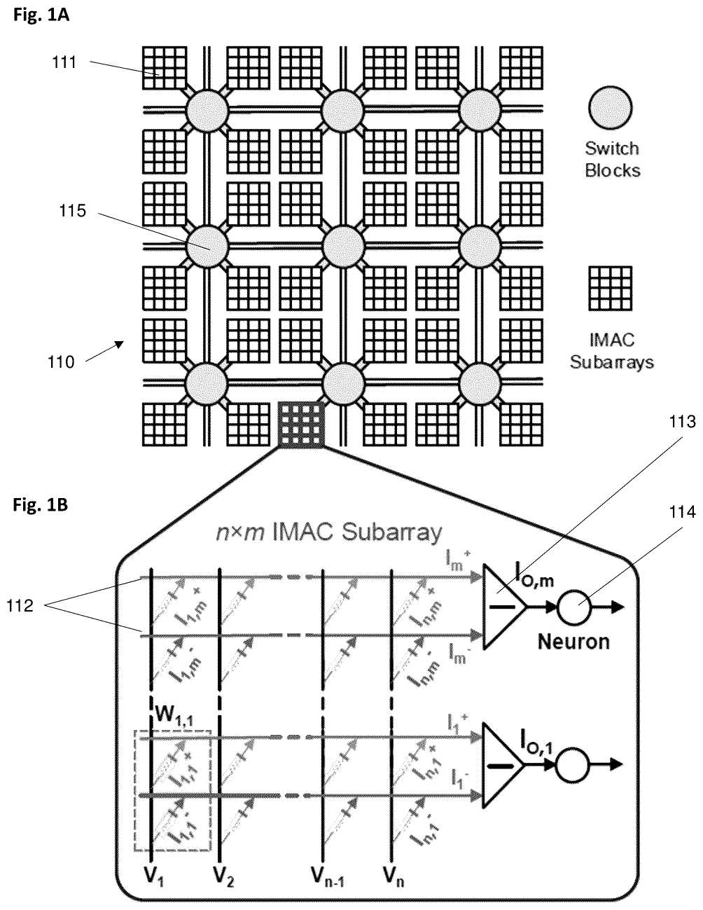

FIGS. 1A and 1B illustrate example structures of architectures for IMACs 110 used in the system architecture 100, according to certain embodiments. These IMAC architectures consist of a set of closely interconnected subarrays 111, linked by programmable switch blocks 115. Each of the IMAC subarrays 111 is made up of memristive crossbars 112 leading to differential amplifiers 113, and analog neuron circuits 114, as depicted in FIG. 1B. For the sake of simplicity, FIG. 1B exclusively illustrates the read path of the subarrays 111, to focus on the inference phase of the neural network. The synaptic connections of the DNN are created by the memristive crossbars 112, which have a number of columns and rows that can be defined based on the number of inputs and output nodes in a single FC layer of the CNN, respectively. The memristor crossbars 112 execute the MVM operation in the analog domain using physical mechanisms like Ohm's law and Kirchhoff's law in electrical circuits. Specifically, the multiplication operation is performed according to Ohm's law (I=GV), while the accumulation operation is based on the conservation of charge, as explained by Kirchhoff's law.

During the configuration phase, when the conductivity of the memristive crossbars 112 is adjusted, adjusting the relative conductance of two memristive crossbars 112 connected to a differential amplifier 113 enables the realization of zero, positive and negative weights 171 in the system architecture 100. FIG. 1B illustrates that the differential amplifiers 113 are linked to two adjacent rows in the memristive crossbar 112 that are labeled + and −, representing positive and negative rows of conductances, respectively. The differential pair of memristive crossbars 112 with conductance values of G⁺_{i,j} and G⁻_{i,j} is used to realize each weight value W_{i,j}, where W_{i,j}∝G⁺_{i,j}−G⁻_{i,j}. Thus, a pair of memristive crossbars 112 having G⁺_{i,j}=1/R_{high} and G⁻_{i,j}=1/R_{low} is used to implement negative weight and vice versa. The zero weight is realized if G⁺_{i,j}=G⁻_{i,j}.

During the inference phase, when input data is fed into the CNN and propagates forward through the CNN until the output layer is reached, the write word lines (WWLs) are disabled, and the read word lines (RWLs) are enabled. This process generates two types of currents, I+ and I−, as shown in FIG. 1B, with the current amplitude depending on the input signals and the resistances of the memristive crossbars 112. The memristive crossbars 112 function as synapses. Each row of memristive crossbars 112 shares a differential amplifier 113 that produces an output voltage proportional to the difference between the currents of the two word lines for that row, i.e., Σi (I⁺_{i,n}−I⁻_{i,n}), where i is the total number of nodes in the input layer, and n is the row number. Finally, the output of the differential amplifiers 113 is fed to the analog neuron circuits 114 to compute the activation functions. This architecture of the IMAC 110 performs both MVM operations and neuron activation functions in each subarray 111 for a given layer and then passes the result to the next subarray 111 to compute the next layer. The IMAC 110 uses an analog sigmoid neuron as the analog neuron circuit 114, which is composed of two resistive devices and a complementary metal-oxide-semiconductor (CMOS) based inverter. The resistive devices in the analog neuron circuit 114 form a voltage divider that reduces the slope of the inverter's linear operating region, resulting in a smooth high-to-low voltage transition that creates a sigmoid function.

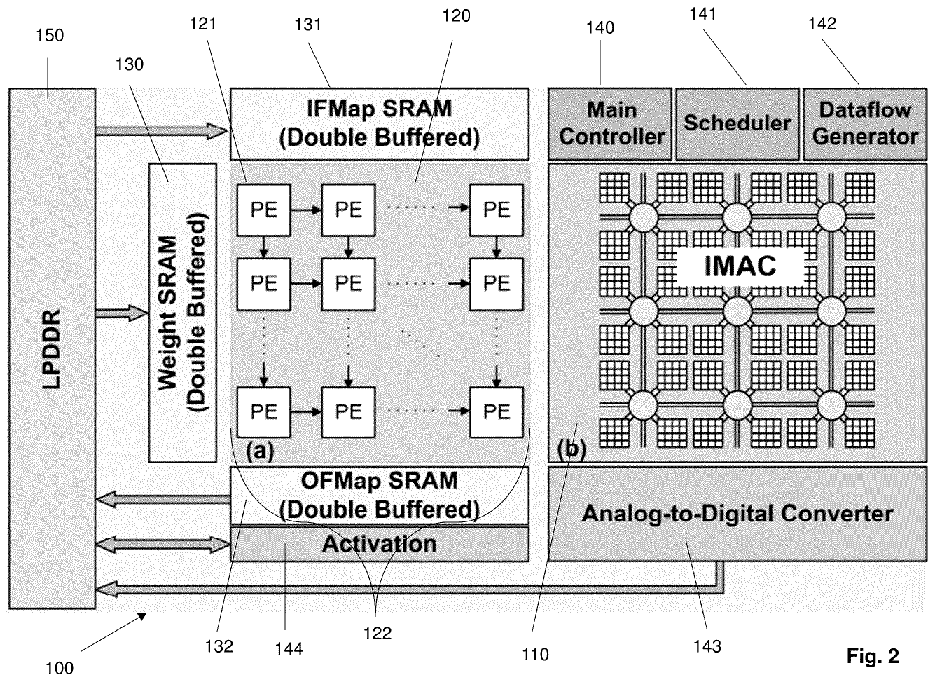

FIG. 2 illustrates an exemplary embodiment of the system architecture 100. The structure of architecture for a digital unit 120 in the system architecture 100 encompasses at least one systolic array 122 comprised of multiple PEs 121. The PEs 121 may include multiply-and-accumulate (MAC) units responsible for executing matrix-matrix, vector-vector, and matrix-vector multiplications. The systolic array 122 enhances performance by reusing values retrieved from memory and registers, consequently minimizing reads and writes to buffers.

Input data is concurrently fed into the systolic array 122, usually propagating in a diagonal wavefront pattern which is commonly used in systolic arrays. The fundamental architecture of the PE 121 influences data flow within the systolic array 122, and varying data flow architectures impact power consumption, percentage of hardware utilization, and overall performance. It should be noted that while in one embodiment the digital unit 120 includes the TPUs developed by Google®, other embodiments may utilize other processors using systolic arrays, such as, but not limited to, a central processing unit (CPU) or a graphics processing unit (GPU) integrated with a systolic array.

Data flow in the systolic array 122 for neural network processing is deliberately arranged to extract data and generate output results in a deterministic sequence that optimizes utilization of the PEs 121, which are the primary operators in deep learning methodologies. Data flow in the system architecture 100 shown in FIG. 2 follows an output stationary (OS) method. The term “stationary” indicates that the data remains within the PEs 121 and does not travel through registers while carrying out operations with the PEs 121. Under the OS method, each pixel of the output feature map (OFMap) 173 is assigned to a given PE 121. During each cycle, weights 171 to multiply the affixed outputs are broadcasted across the PEs 121, yielding partial sums at every clock cycle. FIG. 2 illustrates the architecture of an OS systolic array 121, where the weights 171 are introduced from the left side of the array and the input feature map (IFMap) 172 is streamed in from the top. Each PE 121 is accountable for generating an OFMap 173. Other data flow methods can be used with the system architecture 100, including, but not limited to, input stationary data flow (IS), weight stationary (WS), row stationary (RS), and no-local reuse (NLR) methods.

The system architecture 100, illustrated in FIG. 2, retains the beneficial functionality of the systolic array while enhancing overall performance by incorporating IMAC subarrays 111 directly connected to the PEs 121 within the systolic array 122. Because the OS architecture is utilized with the systolic array 122, its ability to fix OFMaps data 173 in corresponding PEs 121 is capitalized. In an embodiment, to fully utilize the system architecture 100 with a n×n size systolic array 122, the CNN models are modified to have exactly n² elements in the linear vector fed to the FC layer after flattening the last convolutional layer's OFMap 173. This way, the OFMap 173 of the last convolutional layer, computed and stored in the systolic array 122, can be directly transferred to the IMAC 110 without the need to transfer data to and from memory. This enables direct connection of the most significant bit (sign bit) of each OFMap 173 to the IMAC inputs, facilitating the immediate transfer of convolutional layer results from the systolic array to the IMAC for executing the subsequent FC layer, depending on the neural network topology. Data quantization occurs without the need for specialized hardware or software functions by connecting the sign bit through an inverter, converting positive OFMaps (≥0) to a high logic bit ‘1’ and negative OFMaps (high sign bit) to a low logic bit ‘0’. This single-bit precision data is connected to the IMAC inputs via a tri-state buffer component 145 controlled by the main controller component 140 during FC layer execution on the IMAC 110.

Within the system architecture 100, the scheduler component 141 controls the execution of each layer and is programmed according to the CNN topology. The dataflow generator component 142 generates traces (addresses) 175 for an on-board memory device 150 to read data and send it to the IFMap memory 131 and weight memory 130, or to write results from the OFMap memory 132 or the ADC component 143 to the on-board memory device 150 based on the OS dataflow methods. The main controller component 140 manages the enable signals 174 of each component and the tri-state buffer components 145 between the systolic array 122 and the IMAC 110. Each PE 121 within the systolic array contains a full-precision 32-bit floating-point (FP) MAC unit, while the IMAC 110 utilizes ternary weights and binary inputs as already explained. This unique combination of precision and mixed-signal technology within the system architecture 100 offers an innovative approach to enhancing CNN inference performance.

The system architecture 100 employes an on-board memory device 150. In embodiments, the on-board memory device 150 employed by the system architecture 100 is a low-power double data rate (LPDDR) dynamic random access memory (DRAM) component, which is suitable for edge devices due to its lower operating voltage and power-saving modes. It should be noted that other embodiments may use other DRAM devices. The memory device 150 is responsible for storing and retrieving neural network IFMap data 172, weight data 171, and OFMap data 173 according to the dataflow generator component 142 and main controller component 140. Typically, data is pre-loaded into memory device 150, and when the system begins workload execution, the dataflow generator component 142 generates read address traces 175 for retrieving IFMaps 172 and weights 171 from memory device 150, sending them to IFMap memory 131 and weight memory 130, respectively, based on the OS dataflow method. The main controller component 140 facilitates this data transfer, following the request by the scheduler component 141.

After executing the first convolutional layer, OFMap data 173 is forwarded from the PEs 121 to the OFMap memory 132 and then transferred to memory device 150 according to the OS dataflow method and write address traces 175 from the dataflow generator component 142. The scheduler component 141 is responsible for scheduling each layer of the CNN workload, while the dataflow generator component 142 and main controller component 140 manage the overall flow of CNN workload execution. Depending on the CNN workload, the scheduler component 141 may need to execute one or more FC layers. In this case, the scheduler component 141 informs the main controller component 140, which enables data movement between the sign signals of each OFMap 173 (stored in each PE 121 of the systolic array 122) and the inputs of the IMAC 110 by activating the in-between tri-state buffer components 145. The input data of the FC layers are in low or high logic form, while IMAC weights 171 utilize ternary logic (with values 1, 0, and −1).

The CNN workload is trained on the system architecture 100 to mitigate potential accuracy loss resulting from low-precision analog computation. Once the data moves from the systolic array 122 to the IMAC 110, the IMAC 110 executes the required FC layers based on the request from the scheduler component 141, with each FC layer executed in a single clock cycle. This improves performance by allowing reuse of weights 171 and not requiring multiple clock cycles to execute, benefits which are not found in other systems. As described above, the FC weights are pre-loaded onto the memristive crossbars 112 within the IMAC subarrays 111 in the configuration phase.

Upon completing the FC layer execution on the IMAC 110, the results are converted to digital format using the analog-to-digital converter (ADC) component 143 attached to the IMAC 110, and then written back to LPDDR 150 for user access.

It is noteworthy that the system architecture 100 does not require a digital-to-analog converter (DAC) since the IMAC 110 accepts binarized inputs that are coming directly from the sign-bit of each PE 121 in the systolic array 122, resulting in reduced power consumption. If an activation or normalization layer 176 is required, a specialized hardware activation component 144 is implemented outside the systolic array 122 to perform these operations accordingly. FIG. 2 also depicts the dataflow between components of the system architecture 100 using arrows for simplification.

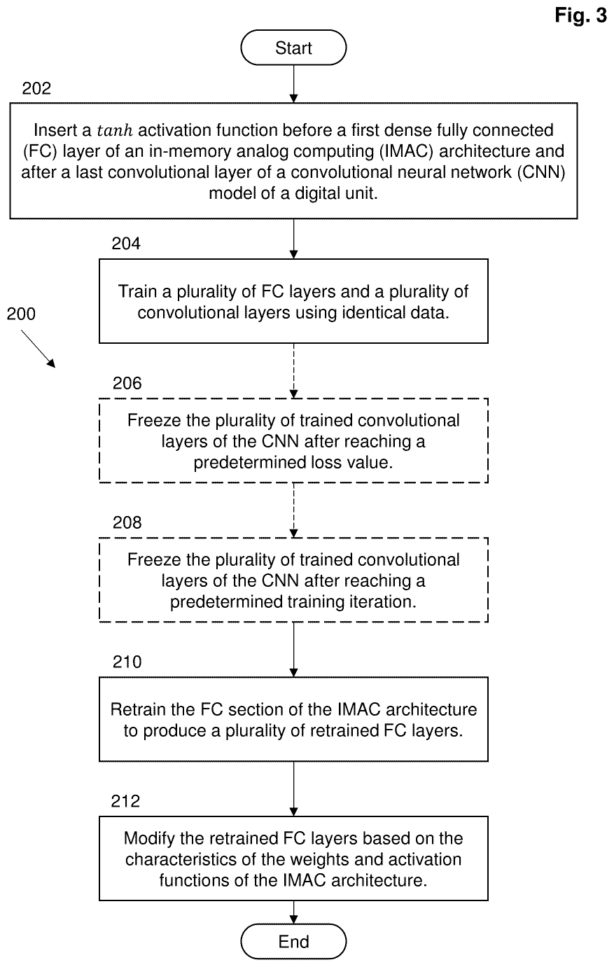

A custom-developed hardware-aware unified training component 160 fully exploits the advantages of the system architecture 100 while maintaining accuracy. The mixed-precision and mixed-signal system architecture 100 has computational constraints and unique features, which the unified training component 160 takes into account. FIG. 3 is a flowchart of a unified training method 200 used by the unified training component 160 on the system architecture 100 to adjust the weight values in the CNN models for various applications based on the hardware constraints existing in the system architecture 100.

In block 202, the unified training component 160 inserts a tanh activation function before a first dense fully connected (FC) layer of the IMAC 110 and after a last convolutional layer of the CNN model of the digital unit 120. This block ensures that activations stay within a range of {−1, 1}.

In block 204, the unified training component 160 trains a plurality of FC layers and a plurality of convolutional layers using identical data. This block produces a plurality of trained FC layers and a plurality of trained convolutional layers. In various embodiments, the training method may be a backpropagation method, a reinforcement learning method, an unsupervised learning method, or any other machine learning training method known in the art.

In optional block 206, the unified training component 160 freezes the plurality of trained convolutional layers of the CNN after reaching a predetermined loss value. This block ensures that the unified training component 160 may continue to modify the FC section of the IMAC 110 without making further changes to the trained convolutional layers.

In optional block 208, the unified training component 160 freezes the plurality of trained convolutional layers of the CNN after reaching a predetermined training iteration. This block ensures that the unified training component 160 may continue to modify the FC section of the IMAC 110 without making further changes to the trained convolutional layers.

In block 210, the unified training component 160 retrains the FC section of the IMAC 110 to produce a plurality of retrained FC layers. The unified training component 160 uses ternary weights by replacing the tanh activation function from block 202 with a sign function to produce input values of −1 and 1 for the plurality of FC layers of the FC section. This block is important because by restricting the inputs of the plurality of FC layers to −1 and 1, the unified training component 160 only needs to transfer the sign bit of the last convolution layer's OFMaps 173 to the IMAC 110. Because only the signbit is transferred, the system architecture 100 does not require any digital-to-analog converter (DAC) units, which reduces power consumption of the system architecture 100. Further, utilizing extremely low precision representations, such as ternary weight values represented by only 2 bits, can considerably reduce CNN memory usage. In certain embodiments, the unified training component 160 completely retrains the entire FC section, starting with any untrained FC layers and continuing with the plurality of trained FC layers from block 204. In other embodiments, only the plurality of trained FC layers from block 204 are retrained.

In block 212, the unified training component 160 modifies the retrained FC layers based on the characteristics of the weights and activation functions of the IMAC 110. The present embodiment employs the ternary synapses and sigmoid activation functions that can be realized using RRAM-based synapses and neurons. Other embodiments may utilize different weight precisions and activation functions.

Table 1 below presents the activation functions and precision of weights in convolutional and dense fully connected layers for each block of the unified training method 200. In block 208 of the unified training method 200, the FC layers are trained using ternary weights, while in the backward pass at block 202 and 204, FP weights are used. After retraining with ternary weights at blocks 208 and 210, only the ternary weights are kept. It is worth noting that most existing CNN models use rectified linear units (ReLUs) to achieve a nonsaturating nonlinearity because of their implementation simplicity and performance benefits compared to digital implementations of tanh and sigmoid activation functions. However, in the IMAC 110, the analog neuron circuits 114 realize high-performance sigmoidal activation functions, which provide accuracy benefits with minimal performance overheads. Although ReLU is still used in the convolutional layers implemented on the digital unit 120, in IMAC 110, analog sigmoidal activation functions are used. To fully utilize the system architecture 100 with a 32×32 systolic array size, the CNN models are modified to have exactly 1024 elements in the linear vector fed to the dense layer after flattening the last convolutional layer's OFMap 173. This way, the OFMap 173 of the last convolutional layer, computed and stored in the digital unit 120, can be directly transferred to the IMAC 110 without the need to transfer data to and from the main memory. For VGG9 and ResNet, this is achieved by increasing the number of channels in the final convolutional layer and decreasing the strides on the MaxPooling layer, while for MobileNetV1 and MobileNetV2, this is accomplished by increasing the number of channels in the final convolutional layer.

TABLE 1
The weights and activations in different stages
of the proposed TPU-IMAC-aware learning algorithm

| | | | Forward | Backward |
|---|---|---|---|---|
| Step | Layers | Component | Pass | Pass |
| 1 | All | Weights | wᵢ ∈ R | wᵢ ∈ R |
| | | Neuron | ReLU | ReLU |
| 2 | Conv | Weights | Frozen | |
| | | Act. | ReLU | |
| | FC | Weights | Wᵢ ∈ {−1, 0, +1} | wᵢ ∈ R |
| | | Neuron | sigmoid | sigmoid |

Experiments on seven different CNN architectures, including LeNet for the MNIST dataset, VGG-9, MobileNet V1 and V2, and ResNet-18 for the CIFAR-10 dataset, and MobileNet V1 and V2 for CIFAR-100 dataset, were conducted to assess the benefits of using system architecture 100 over pure TPU architecture. The models trained for TPU architecture utilized FP32 precision, while models using system architecture 100 are mixed-precision models that incorporated FP32 convolutional layers and ternary dense layers. The accuracy values obtained for both TPU architectures and system architecture 100 are presented in Table 2 below. The simulation results indicate a minimal accuracy drop of less than 1% for the CIFAR-10 dataset for the system architecture 100 implementation. Specifically, the VGG-9 and ResNet-18 models experienced the maximum and minimum accuracy drop of 0.59% and 0.12%, respectively. For the LeNet dataset, the accuracy drop is 1.13% which can be attributed to its larger ratio of FC-to-Conv layers. Finally, a near 3% accuracy drop for mixed-precision models deployed on system architecture 100 for CIFAR-100 dataset can be due to the complexity of the dataset and larger size of the FC layers compared to those of the CNN models used for CIFAR-10 dataset.

TABLE 2
Accuracy, memory utilization and execution time for different CNN models.

| | | | | Memory (MB) | | | | | |
|---|---|---|---|---|---|---|---|---|---|
| | | Accuracy (%) | | | TPU-IMAC | | | Cycles (×10³) | |
| | | | TPU- | TPU | | | | | TPU- |
| Model | Dataset | TPU | IMAC | SRAM | SRAM | RRAM | Total | TPU | IMAC |
| LeNet | MNIST | 98.95 | 97.82 | 0.177 | 0.01 | 0.01 | 0.02 | 2.475 | 0.956 |
| VGG9 | CIFAR- | 90.9 | 90.31 | 38.747 | 34.512 | 0.265 | 34.776 | 331 | 297.18 |
| MobileNetV1 | 10 | 92.89 | 92.7 | 16.976 | 12.74 | 0.265 | 13.005 | 214.9 | 181.1 |
| MobileNetV2 | | 93.73 | 93.43 | 12.904 | 8.668 | 0.265 | 8.933 | 338.7 | 304.9 |
| ResNet-18 | | 94.96 | 94.84 | 48.872 | 44.637 | 0.265 | 44.902 | 681.7 | 647.8 |
| MobileNetV1 | CIFAR- | 66.21 | 63.07 | 17.344 | 12.74 | 0.288 | 13.028 | 218 | 181.1 |
| MobileNetV2 | 100 | 73.06 | 70.14 | 13.272 | 8.668 | 0.288 | 8.956 | 356 | 319.1 |

Consideration of memory footprint is crucial when deploying ML workloads on edge devices with limited resources. Dense FC layers in CNN models often contribute significantly to memory usage. To address this, utilizing extremely low precision representations, such as ternary weight values represented by only 2 bits, can considerably reduce CNN models' memory usage. Table 2 above and Table 3 below provide comparisons of memory utilization for single-precision FP models deployed on TPU and mixed-precision models deployed on system architecture 100. Simulation results demonstrate that the system architecture 100 effectively reduces memory usage for the investigated CNN models, thanks to its hybrid memory architecture that integrates conventional static random-access memory (SRAM) cells with emerging resistive memory technologies like RRAM. Particularly, the system architecture 100 requires 88.34%, 18.13%, and 28.7% less storage on average compared to TPU for CNN models created for LeNet, CIFAR-10, and CIFAR-100 datasets, respectively.

TABLE 3
TPU-IMAC accuracy, performance, and memory reduction
compared to TPU for various CNN models

| | | Accuracy | Memory | |
|---|---|---|---|---|
| Model | Dataset | Difference | Reduction | Speedup |
| LeNet | MNIST | −1.13% | 88.34% | 2.59 |
| VGG9 | CIFAR-10 | −0.59% | 10.25% | 1.11 |
| MobileNetV1 | | −0.19% | 23.39% | 1.19 |
| MobileNetV2 | | −0.30% | 30.77% | 1.11 |
| ResNet-18 | | −0.12% | 8.12% | 1.05 |
| MobileNetV1 | CIFAR- | −3.14% | 24.89% | 1.2 |
| MobileNetV2 | 100 | −2.92% | 32.52% | 1.12 |

A performance analysis of the system architecture 100 used a Scale-Sim simulator. Scale-Sim is a cycle-accurate and architectural-level simulation tool specifically designed for systolic array-based accelerators that execute CNNs. The tool offers flexible simulation options, including the ability to vary systolic array architecture parameters such as size, dataflow specifications (IS, WS, and OS), as well as DRAM and SRAM sizes, and offsets for the IFMap, weight, and OFMap. Leveraging Scale-Sim allowed evaluation of the performance of the system architecture 100 under various configurations and scenarios, providing insights into its potential benefits and limitations for executing CNN workloads on mobile devices.

Scale-Sim was provided with detailed information regarding the CNN workload, including the dimensions of each layer, the IFMap dimensions, weight dimensions, and the number of channels for each layer. Scale-Sim leveraged this information to report the clock cycles required to execute each layer, hardware utilization percentage, memory bandwidth, and DRAM index traces for the entire CNN execution. The clock cycles required for each layer were then aggregated to determine the total number of clock cycles needed for the entire CNN workload. The system architecture 100 enables the execution of each FC layer in just one cycle, and therefore, the overall performance improvement can be calculated by dividing the total number of clock cycles required for the entire workload on the TPU alone by the sum of the clock cycles needed to execute the convolutional layers on the digital unit 120 and the clock cycles required to run the FC layers on the integrated IMAC 110. It is important to highlight that due to the direct connection between the PEs 121 in the systolic arrays 122 and the IMAC 110, no cycles are wasted transferring data between the systolic array 122 and the IMAC 110.

Table 2 above presents the execution times in cycles while running the CNN on both the TPU and the system architecture 100. The results presented in Table 3 above reveal a significant improvement in performance when using the system architecture 100, particularly for the LeNet model with the MNIST dataset, where a 2.59× performance improvement was observed. Furthermore, improvements ranging between 1.05×−1.2× were observed while executing other models such as VGG, MobileNetV1, MobileNetV2, and ResNet-18. These variations in performance improvement can be attributed to the size and number of FC layers executed on the IMAC in each model. Specifically, larger sizes and more FC layers in a CNN model tend to result in greater performance improvements when using the system architecture 100. These findings demonstrate the potential benefits of the architecture for executing CNN workloads on mobile devices, particularly those with a large number of FC layers.

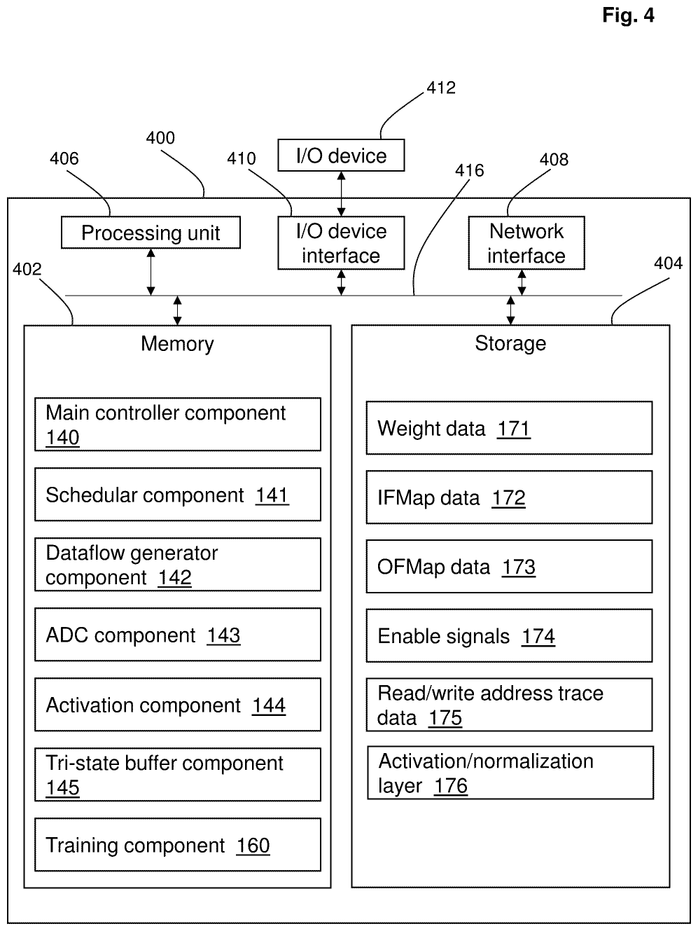

FIG. 4 depicts an example diagram of a computer system 400 that may include the kinds of software programs, data stores, hardware, and interfaces that can implement and train a system architecture 100 as disclosed herein and according to certain embodiments. The computing system 400 may be used to implement embodiments of portions of the system architecture 100 and/or in carrying out embodiments of unified training method 200.

As shown, the computer system 400 includes, without limitation, a memory 402, a storage 404, a processing unit 406, and a network interface 408, each connected to a bus 416. The computing system 400 may also include an input/output (I/O) device interface 410 connecting I/O devices 412 (e.g., keyboard, display, and mouse devices) and/or a network interface 408 to the computing system 400. Further, the computing elements shown in computer system 400 may correspond to a physical computing system (e.g., a system in a data center), a virtual computing instance executing within a computing cloud, and/or several physical computing systems located in several physical locations connected through any combination of networks and/or computing clouds.

Computing system 400 is a specialized system specifically designed to perform the steps and actions necessary to execute unified training method 200 and system architecture 100. While some of the component options for computing system 400 may include components prevalent in other computing systems, computing system 400 is a specialized computing system specifically capable of performing the steps and processes described herein.

The processor 406 retrieves, loads, and executes programming instructions stored in memory 402. The bus 416 is used to transmit programming instructions and application data between the processor 406, I/O interface 410, network interface 408, and memory 402. Note, the processor 406 can comprise a microprocessor and/or other circuitry that retrieves and executes programming instructions from memory 402. processor 406 can be implemented within a single processing element (which may include multiple processing cores) but can also be distributed across multiple processing elements (with or without multiple processing cores) or sub-systems that cooperate in existing program instructions. Examples of processors 406 include central processing units, application-specific processors, and logic devices, as well as any other type of processing device, a combination of processing devices, or variations thereof. While there are a number of processing devices available to comprise the processor 406, the processing devices used for the processor 406 are particular to this system and are specifically capable of performing the processing necessary to execute unified training method 200 and system architecture 100.

The memory 402 can comprise any memory media readable by processor 406 that is capable of storing programming instructions and able to meet the needs of the computing system 400 and execute the programming instructions required for unified training method 200 and system architecture 100. Memory 402 is generally included to be representative of a random-access memory. In addition, memory 402 may include volatile and non-volatile, removable, and non-removable media implemented in any method or technology for storage of information, such as computer-readable instructions or program components. The memory 402 may be implemented as a single memory device but may also be implemented across multiple memory devices or sub-systems. The memory 402 can further include additional elements, such as a controller capable of communicating with the processor 406.

Illustratively, the memory includes multiple sets of programming instructions for performing the functions of the system architecture 100 and unified training method 200, including, but not limited to, main controller component 140, schedular component 141, dataflow generator component 142, ADC component 143, activation component 144, tri-state buffer component 145, training component 160, all of which are discussed in greater detail herein. Although memory 402, as depicted in FIG. 4, includes seven sets of programming instruction components in the present example, it should be understood that one or more components could perform single- or multi-component functions. It is also contemplated that these components of computing system 400 may be operating in a number of physical locations.

The storage 404 can comprise any storage media readable by processor 406 and is capable of storing data that is able to meet the needs of computing system 400 and store the data required for unified training method 200 and system architecture 100. The storage 404 may be a disk drive or flash storage device. The storage 404 may include volatile and non-volatile, removable, and non-removable media implemented in any method or technology for storage of information. Although shown as a single unit, the storage 404 may be a combination of fixed and/or removable storage devices, such as fixed disc drives, removable memory cards, optical storage, network-attached storage (NAS), or a storage area-network (SAN). The storage 404 can further include additional elements, such as a controller capable of communicating with the processor 406.

Illustratively, the storage 404 may store data such as but not limited to, all of which are also discussed in greater detail herein. Illustratively, the storage 404 may also store data such as but not limited to weight data 171, IFMap data 172, OFMap data 173, enable signals 174, read/write address trace data 175, activation or normalization layer 176.

Examples of memory and storage media include random access memory, read-only memory, magnetic discs, optical discs, flash memory, virtual memory, and non-virtual memory, magnetic sets, magnetic tape, magnetic disc storage, or other magnetic storage devices, or any other medium which can be used to store the desired software components or information that may be accessed by an instruction execution system, as well as any combination or variation thereof, or any other type of storage medium. In some implementations, one or both of the memory and storage media can be a non-transitory memory and storage media. In some implementations, at least a portion of the memory and storage media may be transitory. Memory and storage media may be incorporated into computing system 400. While many types of memory and storage media may be incorporated into computing system 400, the memory and storage media used is capable of executing the storage requirements of unified training method 200 and system architecture 100 as described herein.

The I/O interface 410 allows computing system 400 to interface with I/O devices 412. I/O devices 412 can include one or more graphical user interfaces, desktops, a mouse, a keyboard, a voice input device, a touch input device for receiving a gesture from a user, a motion input device for detecting non-touch gestures and other motions by a user, and other comparable I/O devices and associated processing elements capable of receiving input. The I/O devices 412 can also include devices such as a video display or graphical display and other comparable I/O devices and associated processing elements capable of providing output. Speakers, printers, haptic devices, or other types of output devices may also be included in the I/O device 412.

A user can communicate with computing system 400 through the I/O device 412 in order to view weight data 171, IFMap data 172, OFMap data 173, enable signals 174, read/write address trace data 175, activation or normalization layer 176 or complete any number of other tasks the user may want to complete with computing system 400. I/O devices 412 can receive and output data such as but not limited to weight data 171, IFMap data 172, OFMap data 173, enable signals 174, read/write address trace data 175, activation or normalization layer 176.

As described in further detail herein, computing system 400 may receive and transmit data from and to the network interface 408. In embodiments, the network interface 408 operates to send and/or receive data, such as but not limited to, weight data 171, IFMap data 172, OFMap data 173, enable signals 174, read/write address trace data 175, activation or normalization layer 176 to/from other devices and/or systems to which computing system 400 is communicatively connected, and to receive and process interactions as described in greater detail above.

It should be understood that the various techniques described herein may be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), and so forth. The methods and apparatus of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computer, the machine becomes an apparatus for practicing the presently disclosed subject matter.

Although certain implementations may refer to utilizing aspects of the presently disclosed subject matter in the context of one or more stand-alone computer systems, the subject matter is not so limited but rather may be implemented in connection with any computing environment, such as a network or distributed computing environment. Still further, aspects of the presently disclosed subject matter may be implemented in or across a plurality of processing chips or devices, and storage may similarly be affected across a plurality of devices. Such devices might include personal computers, network servers, and handheld devices, for example.

This novel system architecture 100 can achieve a performance improvement ranging between 5%-158% depending on the number and size of FC layers in the CNN workload. Furthermore, analysis reveals that the system architecture 100 can significantly reduce memory requirements by 8%-88%, depending on the model. These improvements follow Amdahl's law and are proportional to the ratio of FC layers to convolutional layers. In addition, as IMAC uses ternary weights, the unified training component 160 was developed using an architecture-aware mixed-precision CNN model training methodology to mitigate potential accuracy drops. Results show that this methodology incurs a minimal accuracy drop for CNN models deployed on the system architecture 100. In particular, accuracy drops ranged between 0.12% and 0.59% for CIFAR-10, 1.13% for MNIST, and nearly 3% for CIFAR-100 datasets. These findings highlight the potential benefits of using system architecture 100 for CNN inference on mobile devices, and provides several opportunities for future work.

It is to be understood that this written description uses examples to disclose the invention, including the best mode, and also to enable any person skilled in the art to make anew the invention. The various embodiments of the invention may be combined in any arrangement capable of producing the invention. Any dimensions or other size descriptions are provided for purposes of illustration and are not intended to limit the scope of the claimed invention. Additional embodiments can include variations component composition, synthesis, and combination, as well as variations required for use in the industry. The patentable scope of the invention may include other examples that occur to those skilled in the art.

What is claimed is:

1. A hybrid computing device, comprising:
an in-memory analog computing (IMAC) architecture comprising a plurality of interconnected subarrays;
an analog-to-digital converter interconnecting the IMAC architecture with a memory unit; and
a systolic array operably connected to the memory unit.

2. The device of claim 1, wherein the plurality of interconnected subarrays are linked by a plurality of programmable switch blocks.

3. The device of claim 1, wherein each of the plurality of interconnected subarrays is made up of a plurality of memristive crossbars leading to a plurality of differential amplifiers and a plurality of analog neuron circuits.

4. The device of claim 1, wherein the memory unit is a dynamic random access memory (DRAM).

5. The device of claim 4, wherein the DRAM is a low-power double data rate (LPDDR) DRAM.

6. The device of claim 1, wherein the systolic array comprises a plurality of processing elements (PEs).

7. The device of claim 6, wherein the PEs comprise multiply-and-accumulate (MAC) units responsible for executing matrix-matrix, vector-vector, and matrix-vector multiplications.

8. The device of claim 1, wherein the systolic array is a tensor processing unit (TPU).

9. The device of claim 1, wherein the systolic array is a central processing unit (CPU) or a graphics processing unit (GPU) integrated with a systolic array.

10. A method of using a unified training component to train the hybrid computing device of claim 1, comprising:
inserting a tanh activation function before a first dense fully connected (FC) layer and after a last convolutional layer to ensure that activations stay within a range of {−1, 1};
training a plurality of FC layers and a plurality of convolutional layers using identical data to produce a plurality of trained FC layers and a plurality of trained convolutional layers;
retraining an FC section of the IMAC architecture to produce a plurality of retrained FC layers;
modifying the plurality of retrained FC layers based on characteristics of weights and activation functions of the IMAC architecture.

11. The method of claim 10, further comprising training the plurality of FC layers and the plurality of convolutional layers using a machine learning training method.

12. The method of claim 11, wherein the machine learning training method is selected from the group consisting of: a backpropagation method, a reinforcement learning method, and an unsupervised learning method.

13. The method of claim 11, further comprising freezing the plurality of trained convolutional layers after reaching a predetermined loss value.

14. The method of claim 11, further comprising freezing the plurality of trained convolutional layers after reaching a predetermined training iteration.

15. The method of claim 10, wherein retraining the FC section of the IMAC architecture utilizes ternary weights.

16. The method of claim 10, wherein retraining the FC section comprises replacing the tanh activation function with a sign function to produce input values of −1 and 1 for the plurality of FC layers of the FC section.

17. The method of claim 10, wherein retraining the FC section comprises retraining the entire FC section, starting with any untrained FC layers from the plurality of FC layers.

18. The method of claim 10, wherein retraining the FC section comprises retraining only the plurality of trained FC layers.

19. The method of claim 10, further comprising modifying the plurality of retrained FC layers by employing ternary synapses and sigmoid activation functions.

20. The method of claim 10, further comprising modifying the plurality of retrained FC layers using RRAM-based synapses and neurons.
